(19) United States
(12) Patent Application Publication
(10) Pub. No.: US 2008/0003831 A1
(43) Pub. Date: Jan. 3, 2008

(54) Method for forming metal pattern in semiconductor device

(75) Inventors: Ki-Hong Yang, Kyoungki-do (KR); Gyu-An Jin, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/647,770

(22) Filed: Dec. 29, 2006

(30) Foreign Application Priority Data
Jun. 29, 2006 (KR) 2006-0059745

(51) Int. Cl. H01L 21/311; H01L 21/302

(52) U.S. Cl. 438/702; 438/704; 438/745; 438/742

(57) ABSTRACT

A method for forming a metal pattern in a semiconductor device includes preparing a semi-finished substrate with a metal layer for use as a metal pattern, performing a cleaning process inducing oxidation over an upper surface of the metal layer to form an anti-scattering reflection layer over the upper surface of the metal layer, forming a photoresist pattern over the anti-scattering reflection layer, and etching the anti-scattering reflection layer and the metal layer exposed by the photoresist pattern to form the metal pattern.

### CROSS-REFERENCE TO RELATED APPLICATIONS

The present invention claims priority of Korean patent application number 10-2006-0059745, filed on Jun. 29, 2006, which is incorporated by reference in its entirety.

### BACKGROUND OF THE INVENTION

The present invention relates to a method for fabricating a semiconductor device, and more particularly, to a method for forming a metal pattern in a semiconductor device.

As semiconductor devices have become highly integrated, the size of devices such as transistors and capacitors has also become very small. Accordingly, a metal pattern that couples such devices is often required to be formed with a very small size. Limitations often occur when a small metal pattern is formed at a portion with less than sufficient level of planarization. For instance, when a metal pattern is formed over a portion with excessive height differences, scattering reflection may be generated at a surface of a metal layer during a photolithography process, resulting in an undesirable photoresist pattern form.

Examples of the undesirable photoresist pattern form include striation, pattern collapse, and abnormal line width change in pattern lines. The abnormal line width change in pattern lines refers to the pattern lines becoming too thin or thick. Accordingly, a technology to additionally form a silicon oxynitride (SiON) layer or a bottom anti-reflective coating (BARC) layer over a metal layer during a formation process of a metal pattern has been introduced to overcome the scattering reflection. However, forming the SiON layer or the BARC layer usually requires performing an extra process, and thus, the formation process of the metal pattern may become complicated.

### SUMMARY OF THE INVENTION

Embodiments of the present invention are directed to provide a method for forming a metal pattern in a semiconductor device, which can reduce scattering reflection generated by a metal while forming the metal pattern, decreasing generation of undesirable photoresist pattern forms and simplifying the fabrication process.

In accordance with an aspect of the present invention, there is provided a method for forming a metal pattern in a semiconductor device, including: preparing a semi-finished substrate with a metal layer for use as a metal pattern; performing a cleaning process inducing oxidation over an upper surface of the metal layer to form an anti-scattering reflection layer over the upper surface of the metal layer; forming a photoresist pattern over the anti-scattering reflection layer; and etching the anti-scattering reflection layer and the metal layer exposed by the photoresist pattern to form the metal pattern.

### BRIEF DESCRIPTION OF THE DRAWINGS

FIGS. 1 to 3 illustrate cross-sectional views showing a method for forming a metal pattern in a semiconductor device in accordance with an embodiment of the present invention.

### DESCRIPTION OF SPECIFIC EMBODIMENTS

The present invention relates to a method for forming a metal pattern in a semiconductor device. According to embodiments of the present invention, a cleaning process inducing oxidation is performed after a metal layer for use as a metal pattern is formed to form an anti-scattering reflection layer including an oxide-based material for insulation over an upper surface of the metal layer. Consequently, undesirable photoresist pattern forms generated by scattering reflection, which is caused by metal during a photolithography process, are reduced. In particular, the cleaning process comprises using a diluted sulfuric acid and hydrogen peroxide (DSP) chemical for inducing oxidation in order to form the anti-scattering refection layer including an oxide-based material for insulation. The DSP chemical includes sulfuric acid (H₂SO₄), hydrogen peroxide (H₂O₂), deionized water, and hydrogen fluoride (HF). Thus, the scattering reflection caused by metal during the photolithography process is reduced, and consequently, typical formation processes for forming a silicon oxynitride (SiON) layer or a bottom anti-reflective coating (BARC) layer for preventing scattering reflection may no longer be needed. Accordingly, the undesirable photoresist pattern forms caused by the scattering reflection during the photolithography process may be reduced and the process may become simplified.

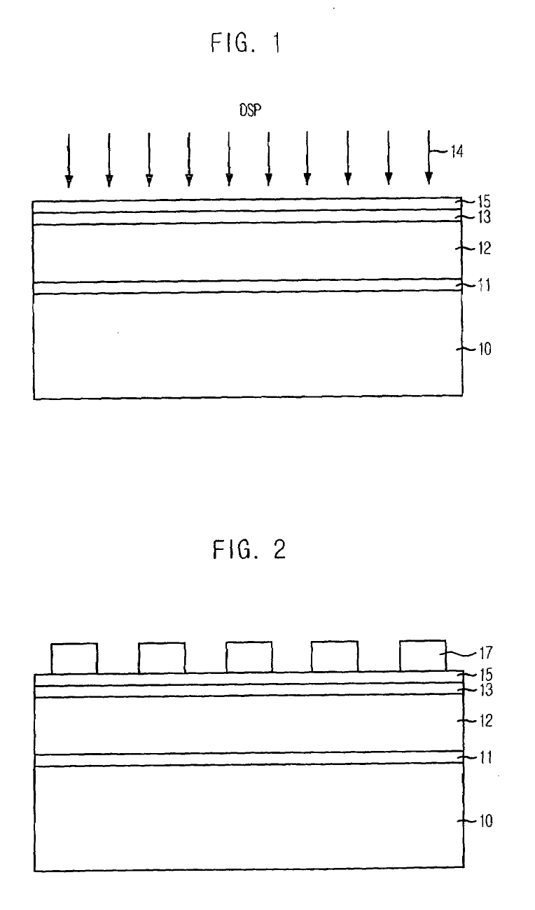

FIGS. 1 to 3 illustrate cross-sectional views showing a method for forming a metal pattern in a semiconductor device in accordance with an embodiment of the present invention.

Referring to FIG. 1, an insulation layer 10 is formed over a semi-finished substrate (not shown) including transistors. Although not shown, the substrate and contact plugs are interposed in the insulation layer 10. The contact plugs are to be formed through a subsequent process.

A diffusion prevention layer 11 is formed over the insulation layer 10. For instance, the diffusion prevention layer 11 may include a stack structure configured with titanium (Ti)/titanium nitride (TiN). A metal layer 12 is formed over the diffusion prevention layer 11. For instance, the metal layer 12 may include tungsten (W) or aluminum (Al).

An anti-reflective coating (ARC) layer 13 is formed over the metal layer 12. The ARC layer 13 may include a stack structure configured with Ti/TiN, a Ti layer, or a TiN layer. The ARC layer 13 may generate scattering reflection because the ARC layer 13 includes metal. Accordingly, formation of the ARC layer 13 may be omitted if necessary.

A cleaning process 14 inducing oxidation is performed on the substrate structure to form an anti-scattering reflection layer 15. The anti-scattering reflection layer 15 includes an oxide-based material. In particular, it may be important to use a diluted sulfuric acid and hydrogen peroxide (DSP) chemical to induce oxidation during the cleaning process 14. The DSP chemical includes a mixed chemical comprising sulfuric acid (H₂SO₄), hydrogen peroxide (H₂O₂), deionized water, and hydrogen fluoride (HF). A ratio of H₂SO₄ to H₂O₂ to deionized water to HF in the DSP chemical ranges approximately 1 to 6:50 to 500:1 to 10:10 to 50.

In more detail, H₂O₂ in the DSP chemical generates oxidation during the cleaning process 14, automatically generating the anti-scattering reflection layer 15 over an upper surface of the metal layer 12. For instance, the anti-scattering reflection layer 15 may be formed over a surface of the ARC layer 13. The anti-scattering reflection layer 15 may be able to reduce scattering reflection generated by metal during a subsequent photolithography process because the anti-scattering reflection layer 15 includes an insulating layer, not a metal. The formation of the anti-scattering reflection layer 15 may be expressed in a chemical equation as shown in Equation 1 provided below.

W+6H₂O₂→WO₃+6H₂O [Equation 1]

### In particular, a detailed equation of Equation 1 is described below in Equation 2.

6H₂O₂+6e−→6H₂O+3O²⁻, H₂O₂: reduction

W+3O²⁻→WO₃+6^{e-}, W⁰: oxidation [Equation 2]

Referring to the above Equations 1 and 2, the metal layer 12 includes tungsten as an example. Thus, the resultant anti-scattering reflection layer 15 includes a tungsten oxide layer.

When the metal layer 12 includes aluminum, the anti-scattering reflection layer 15 includes an aluminum oxide layer. According to this embodiment of the present invention, performing the cleaning process 14 inducing oxidation to automatically form the anti-scattering reflection layer 15 including a metal oxide-based material for insulation over the upper surface of the metal layer 12 may allow reducing scattering reflection generated by the metal layer 12 or the ARC layer 13 including metal. Also, the typical formation processes of a separate silicon oxynitride (SiON) layer or a bottom anti-reflective coating (BARC) layer may be omitted. This is possible because the oxide-based anti-scattering reflection layer 15 can replace the SiON layer or the BARC layer that reduces surface reflection. Accordingly, occurrences of undesirable photoresist pattern forms may be reduced and the formation process of the metal pattern may be simplified during a subsequent photolithography process for forming the metal pattern. For instance, the occurrences of the undesirable photoresist pattern forms may be reduced by decreasing striation, pattern collapse, abnormal line width change of pattern lines, and tails generated in the photoresist pattern.

Since impurities on the upper surface of the metal layer 12 are removed during the cleaning process 14 and an oxidation occurs at the same time, the impurities penetrating between interfaces of the metal layer 12 can be fundamentally reduced. Thus, a resistive characteristic of the metal layer 12 may be stably maintained. For example, large grains are formed when the metal layer 12 is formed. At this time, a crack may be generated in a wafer due to the grains when the substrate (wafer) is severely stressed. However, according to the embodiment of this invention, gaps between the grains become oxide-stuffed by the oxidation, resulting in a lessened stress. Thus, the generation of cracks in the wafer may be decreased.

The anti-scattering reflection layer 15 formed through oxidation over the upper surface of the metal layer 12 prevents a direct contact between the metal layer 12 and a subsequent photoresist pattern, eliminating influences of the metal pattern with respect to a photoresist carbon layer.

Referring to FIG. 2, a photoresist pattern 17 is formed over the anti-scattering reflection layer 15. The photoresist pattern 17 is formed to define the metal pattern. The photoresist pattern 17 is formed by forming a photoresist layer and performing a photo-exposure and developing process using a photo mask. In particular, the anti-scattering reflection layer 15 may prevent scattering reflection, which may be caused by the ARC layer 13 and the metal layer 12, during the photo-exposure process.

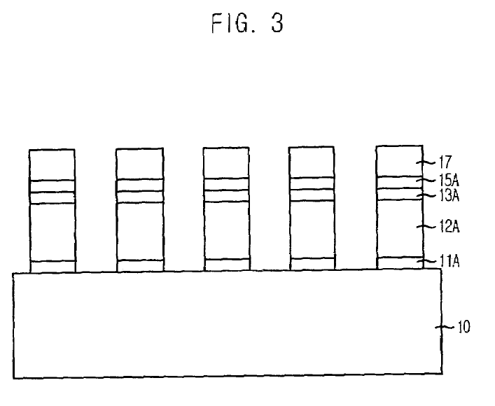

Referring to FIG. 3, an etching process is performed using the photoresist pattern 17 as a mask to sequentially etch the anti-scattering reflection layer 15, the ARC layer 13, the metal layer 12, and the diffusion prevention layer 11. Consequently, an anti-scattering reflection pattern 15A, an ARC pattern 13A, a metal pattern 12A, and a diffusion prevention pattern 11A are formed.

According to this embodiment of the present invention, after forming the metal layer for use as the metal pattern, performing the cleaning process inducing oxidation to form the anti-scattering reflection layer over the upper surface of the metal layer may allow reducing scattering reflection generated by metal during the photolithography process. Also, typical formation processes of a separate silicon oxynitride (SiON) layer or a bottom anti-reflective coating (BARC) layer for use as an anti-scattering reflection layer may be omitted. The anti-scattering reflection layer includes an insulating material. Accordingly, undesirable photoresist pattern forms generated by the scattering reflection may be reduced during the photolithography process for forming the metal pattern in the semiconductor device, and the process may be simplified.

While the present invention has been described with respect to the specific embodiments, it will be apparent to those skilled in the art that various changes and modifications may be made without departing from the spirit and scope of the invention as defined in the following claims.

What is claimed is:

1. A method for forming a metal pattern in a semiconductor device, comprising:
preparing a semi-finished substrate with a metal layer for use as a metal pattern;
performing a cleaning process inducing oxidation over an upper surface of the metal layer to form an anti-scattering reflection layer over the upper surface of the metal layer;
forming a photoresist pattern over the anti-scattering reflection layer; and
etching the anti-scattering reflection layer and the metal layer exposed by the photoresist pattern to form the metal pattern.

2. The method of claim 1, wherein performing the cleaning process comprises using a diluted sulfuric acid and hydrogen peroxide (DSP) chemical.

3. The method of claim 2, wherein the DSP chemical comprises sulfuric acid (H₂SO₄), hydrogen peroxide (H₂O₂), deionized water, and hydrogen fluoride (HF).

4. The method of claim 3, wherein a ratio of the H₂SO₄ to the H₂O₂ to the deionized water to the HF in the DSP chemical ranges approximately 1 to 6:50 to 500:1 to 10:10 to 50.

5. The method of claim 1, wherein the anti-scattering reflection layer comprises a metal oxide-based layer.

6. The method of claim 1, wherein the metal layer comprises one of tungsten and aluminum.

7. The method of claim 1, wherein the anti-scattering reflection layer comprises one of a tungsten oxide layer and an aluminum oxide layer.

8. The method of claim 1, further comprising, forming an anti-reflective coating (ARC) layer including a metal-based material over the metal layer.

9. The method of claim 8, wherein the ARC layer comprises one selected from a group consisting of a stack structure including titanium (Ti) and titanium nitride (TiN), a Ti layer, and a TiN layer.

10. The method of claim 1, further comprising, before forming the metal layer:
forming an insulation layer over the substrate; and
forming a diffusion prevention layer over the insulation layer.

11. The method of claim 10, wherein the diffusion prevention layer comprises a stack structure including Ti and TiN.
